(19) United States
(12) Patent Application Publication
(10) Pub. No.: US 2026/0326616 A1
(43) Pub. Date: Oct. 22, 2026

(54) Method for Operating a Battery Cell for a Motor Vehicle, Computer Program, Data Processing Device, Battery Control Unit, and Motor Vehicle

(71) Applicant: Bayerische Motoren Werke Aktiengesellschaft, Muenchen (DE)

(72) Inventors: Stefan BIELESCH, Muenchen (DE); Andreas BINDEWALD, Muenchen (DE); Julian WIESMEIER, Muenchen (DE)

(21) Appl. No.: 19/103,470

(22) PCT Filed: Aug. 21, 2023
(86) PCT No.: PCT/EP2023/072882

§ 371 Date: Feb. 12, 2025

(30) Foreign Application Priority Data
Aug. 24, 2022 (DE) 10 2022 121 394.3

(51) Int. Cl. B60L 58/24; G01R 31/36; G01R 31/367; G01R 31/374

(52) U.S. Cl. CPC B60L 58/24; G01R 31/3648; G01R 31/367; G01R 31/374; B60L 2240/545; B60L 2240/549

(57) ABSTRACT

A method for operating a battery cell for a motor vehicle includes capturing an actual temperature of the battery cell and an actual current which relates to a power demand on the battery cell, performing a temperature prediction to calculate a cell core temperature on the basis of a thermal model of the battery cell using the actual temperature and the actual current, calculating a continuous current using the temperature prediction, predicting a degradation of a power limit using the temperature prediction and the continuous current, and outputting a control command for the operation of the battery cell using the power limit.

### BACKGROUND AND SUMMARY

The present disclosure relates to a method for operating a battery cell for a motor vehicle, and a data processing device that is configured to execute the method at least partially. Furthermore, a battery control unit and a motor vehicle are provided with the data processing device. In addition or alternatively, a computer program is provided, which comprises commands which, during the execution of the program by a computer, cause this computer to execute the method at least partially. In addition or alternatively, a computer-readable medium is provided, which comprises commands which, during the execution of the commands by a computer, cause this computer to execute the method at least partially.

A maximum current that can be withdrawn by a battery cell or a current limit is limited by a temperature of the battery cell. A relationship between the temperature and the maximum withdrawable current is typically given by tables and/or graphs, what are known as current characteristics maps. At the edges of the current tables, that is to say at low or high temperature, there is a strong dependence of the current limits on the temperature. At the edges, a temperature-dependent degradation of the current and the power of the battery cell is therefore present.

Particularly in the case of insufficient cooling, there may be a rapid heating of the battery cell or a high-voltage battery (HVS). This may lead to an abrupt degradation of the withdrawable current and therefore a withdrawable power. Even a degradation to a drive power of 0 kW cannot be excluded, which is highly undesirable.

Therefore, it is known to store current characteristics maps with temperature-dependent current limits in a memory of a battery management unit. Therefore, a new vehicle test must be carried out for each type of battery cell, in order to record current characteristics maps. The application and safeguarding outlay for creating the current characteristics maps is correspondingly high.

EP2780972A1 discloses a battery comprising at least one battery cell having a housing in which an electrode arrangement is arranged, a first temperature sensor that is arranged outside of the battery cell housing, and a second temperature sensor that is arranged in the interior of the battery cell housing.

Against the background of this prior art, an object of the present disclosure is to specify a method that is suitable for enhancing the prior art. An actual embodiment of the disclosure can achieve an object of enabling a more reliable operation of a battery cell, avoiding abrupt power degradation and reducing safeguarding outlay at the same time.

This object is achieved by the features disclosed herein. The present disclosure also contains optional developments of the disclosure.

Accordingly, this object is achieved by a method for operating a battery cell for a motor vehicle. In this case, the method has the steps: capturing an actual temperature of the battery cell and an actual current relating to a power demand on the battery cell; calculating a continuous current, taking account of the temperature prediction; predicting a degradation of a power limit, taking account of the temperature prediction and the continuous current; and outputting a control command for operating the battery cell, taking account of the power limit.

The actual temperature and the actual current here characterize a current state of the battery cell. Starting from the actual temperature, a temperature different than the actual temperature may result due to a picking up or feeding of the actual current.

The actual temperature and the actual current are used for calculating the cell core temperature, that is to say the temperature in the interior of the battery cell. Chemical reactions take place in the cell core, which are temperature-dependent and thus, in accordance with the cell core temperature, have an influence on internal resistances and time constants of the dynamic battery cell behavior under load. The temperature in the cell core may change owing to the load-related heat production. The thermal model of the battery cell is a mathematical model that gives information about the cell core temperature by a data processing device on the basis of the actual temperature and the actual current.

Here, the thermal model enables a temperature prediction for the cell core temperature, that is to say a calculation of a cell core temperature that is set in the case of a current. The continuous current can be calculated as a result. The continuous current is a current that can be maintained in the case of a particular temperature. The continuous current does not have to be specified depending on the temperature, but rather can be calculated. The safeguarding outlay can thereby be reduced. The control command can be determined on the basis of the continuous current. The control command is output for example by a battery management unit to the battery cells, in order to control the battery cell accordingly.

To output the control command, a power limit that is dependent on the continuous current and the temperature prediction is predicted. Therefore, it is possible that the power degradation no longer has to be stored in a memory, but rather can be calculated specifically for the battery cell.

In other words, the disclosure makes it possible to predict the temperature development in the battery cell using the thermal model of the high-voltage battery or the battery cell. Based on this prediction, the current and therefore the power can be degraded in an early and more customer-worthy manner as a function of the cell core temperature. An abrupt power drop can thus be avoided.

The thermal model may comprise an analytically solvable differential equation. Therefore a temperature prediction for determining the cell core temperature is possible, which can be modeled in a detailed manner and carried out effectively at the same time. The differential equation may have a plurality of parameters for modeling the battery cell. One solution of the differential equation may comprise a sum of exponential functions and/or polynomials and can be analyzed effectively by a data processing device. Therefore, the solution can be stored in a data processing device and the prediction may result from the input or the definition of the parameters. The actual calculation of the cell core temperature can therefore be carried out on the data processing device, for example a battery management unit, in real time.

The thermal model may comprise a plurality of nodes that model the battery cell and have an energy balance for each of the nodes. Here, the nodes may comprise measured temperature values by temperature sensors of the battery cell, temperatures, in particular a maximum and a minimum temperature, of the cell core, and a coolant temperature. Thus, the thermal model may have a detailed energy balance for the nodes and thus the battery cell.

The continuous current can be calculated, taking account of a target temperature. The continuous current is set in the case of a chosen target temperature and current fixed boundary conditions. The continuous current may in this case relate to a stationary state in which the temperature does not change over time. In this state, exact specification of the cell core temperature is possible, as a constant cell core temperature, which is the same as the target temperature, is set in the stationary state.

The power limit can be calculated analytically. Particularly in the case of a known continuous current and known target temperature, the power degradation can be represented as a linear equation. The predicted temperature can be inserted into the linear equation and this results in a quadratic equation which makes it possible to predict the current limit degradation. Due to the analytical calculation, an effective determination of the power limit is possible.

That which is described above can, in other words and in relation to an actual embodiment that is described as non-limiting for the present disclosure, be summarized as follows: The disclosure relates to the cell core temperature prediction for high-voltage system (HVS) power degradation. The background is that the high-voltage battery should be protected from excessive temperature. To this end, the current is degraded in a temperature-dependent manner. It is known to degrade, i.e. to lower or to limit, the current depending on the current temperature. The problem is that it is not known how the temperature will develop in the near future. As a result, it is possible that too much power is released, which results in excessive heating of the high-voltage battery and thus a sudden degradation of the current, possibly as far as a stoppage. The basic principle is that using a thermal model of the high-voltage battery or the cell, the temperature development in the high-voltage battery is predicted. Based on this prediction, it is possible to degrade the power in an early and more customer-worthy manner. For example, by a high-voltage battery thermal model, it is predicted that (at the current temperature 50 °C and load 100 kW), the temperature of the HVS will increase to 60 °C in the next 10 s. As strong degradation begins from 55 °C, and the range 55-60 °C should be avoided, the load is reduced from 100 kW to lower powers (for example 80 kW) even then.

Furthermore, a computer program is provided, which comprises commands which, during the execution of the program by a computer, cause this computer to execute or carry out the above-described method at least partially.

A program code of the computer program may be present in any desired code, particularly in a code that is suitable for controllers of motor vehicles.

That which is described above with reference to the method also applies analogously for the computer program and vice versa.

Furthermore, a data processing device, e.g. a control unit, for a motor vehicle is provided, wherein the data processing device is set up to execute or carry out the above-described method at least partially. Thus, the method is a computer-implemented method.

The data processing device can for example be comprised by a battery management unit (BMU). The data processing device may alternatively be an electronic control unit (ECU). The electronic control unit may be an intelligent processor-controlled unit which can communicate with other modules e.g. via a central gateway (CGW) and which can form the vehicle electrical system possibly by field buses, such as the CAN bus, LIN bus, MOST bus and FlexRay or by automotive ethernet, e.g. together with telematic control units. It is conceivable that the control unit controls functions relevant for the performance of the motor vehicle, such as the engine control unit in particular and the drivetrain, and/or regulates a charging process.

That which is described above with reference to the method and to the computer program also applies analogously for the data processing device and vice versa.

Furthermore, a battery management unit for a motor vehicle is provided, comprising the above-described data processing device.

That which is described above with reference to the method, to the data processing device and to the computer program also applies analogously for the battery management unit (BMU) and vice versa.

Furthermore, a motor vehicle is provided, comprising the above-described data processing device.

The motor vehicle can be a passenger car, particularly an automobile. The optionally automated motor vehicle can be a motor vehicle that can be driven electrically. The motor vehicle may to this end comprise an electric drive that can be loaded with electrical energy, which is provided by the energy storage device, for driving the motor vehicle.

That which is described above with reference to the method, to the data processing device, to the battery management unit and to the computer program also applies analogously for the motor vehicle and vice versa.

Furthermore, a computer-readable medium, particularly a computer-readable storage medium, is provided. The computer-readable medium comprises commands which, during the execution of the program by a computer, cause this computer to execute the above-described method at least partially.

That is to say, a computer-readable medium can be provided, which comprises an above-defined computer program. The computer-readable medium can be any desired digital data storage device, such as for example a USB stick, a hard disk, a CD-ROM, an SD card or an SSD card. The computer program does not necessarily have to be stored on such a computer-readable storage medium in order to be made available to the motor vehicle, but rather can also be obtained via the internet or externally in another way.

That which is described above with reference to the method, to the data processing device, to the computer program and also to the automated motor vehicle also applies analogously for the computer-readable medium and vice versa.

An embodiment is described with reference to FIGS. 1 to 5.

### BRIEF DESCRIPTION OF THE DRAWINGS

FIG. 1 schematically shows a motor vehicle according to an aspect of the disclosure;

FIG. 2 schematically shows a flow chart of a method according to an aspect of the disclosure;

FIG. 3 schematically shows an information flow for carrying out a method according to an aspect of the disclosure;

FIG. 4 shows a thermal model for carrying out a method according to an aspect of the disclosure;

FIG. 5 shows a scenario for carrying out a method according to an aspect of the disclosure;

### DETAILED DESCRIPTION OF THE DRAWINGS

FIG. 1 schematically shows a motor vehicle 200 according to an aspect of the disclosure. The motor vehicle 200 is a motor vehicle 200 that can be driven electrically. For this, the motor vehicle 200 has an electric drive 230 and an energy storage device 210. The energy storage device 210 can load the electric drive 230 with electrical energy 225 which the electric drive 230 can convert into mechanical energy. In this case, the state of charge of the energy storage device 210 falls and heat is created.

The energy storage device 210 comprises a plurality of battery cells 215 and a battery management unit 220 (BMU). Each of the battery cells 215 is set up for a chemical reaction in order to convert chemical energy into electrical energy 225 and vice versa. During such a conversion, heat is created. A battery cell 215 of this type is described further with reference to FIG. 4.

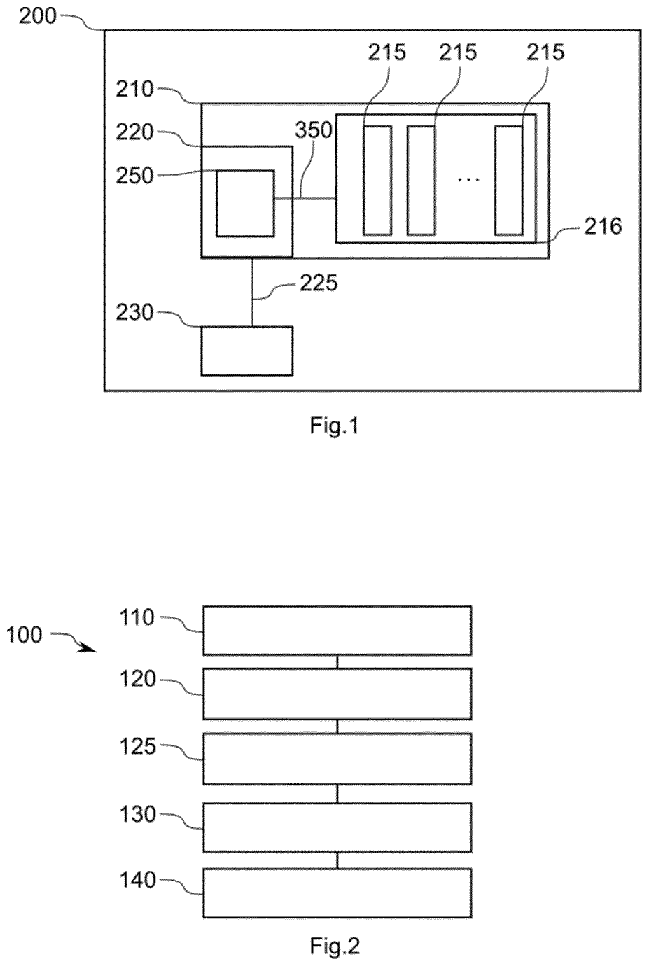

The motor vehicle 200 according to FIG. 1, particularly the battery management unit 220 in the motor vehicle, has a data processing device 250. The data processing device 250 is set up for operating the battery cells 215. For this, the data processing device 250 is set up to transmit a command 350 to the battery cells 215 and/or a battery module 216 comprising a plurality of the battery cells 215. The data processing device 250 is set up to carry out the method 100, which is described with reference to FIGS. 2, 3 and 5, in accordance with the thermal model which is described with reference to FIG. 4.

FIG. 2 schematically shows a flow chart of a method 100 according to an aspect of the disclosure. The method 100 is a method 100 for operating a battery cell 215 for a motor vehicle 200. A motor vehicle 200 of this type is described with reference to FIG. 1. FIG. 2 is described with reference to FIG. 1 and the description thereof.

According to FIG. 2, a capture 110 takes place of an actual temperature TI of the battery cell 215 and an actual current II relating to a power demand on the battery cell 215. To capture the actual temperature TI, temperature sensors 303 can be provided at the battery cell 215 and at a cooling arrangement of the energy storage device 210. The power demand is for example based on an activity of a driver of the motor vehicle 200 and/or on an automated driving function. As a result, a power is demanded by the electric drive 230, for which electrical energy 225 is picked up from the energy storage device 210. This brings about the actual current II of the battery cells 215, which can be measured by a current measuring arrangement.

A temperature prediction 315 is carried out 120 for calculating a cell core temperature TK on the basis of a thermal model 300 of the battery cell 215, taking account of the actual temperature TI and the actual current II. The actual temperature TI and the actual current II are used as input in the thermal model 300. The thermal model 300 is analyzed by the data processing device 250. The thermal model 300 comprises an analytically solvable differential equation 301 and has a plurality of nodes 302 that model the battery cell 315 and an energy balance for each of the nodes 302, see also FIG. 4.

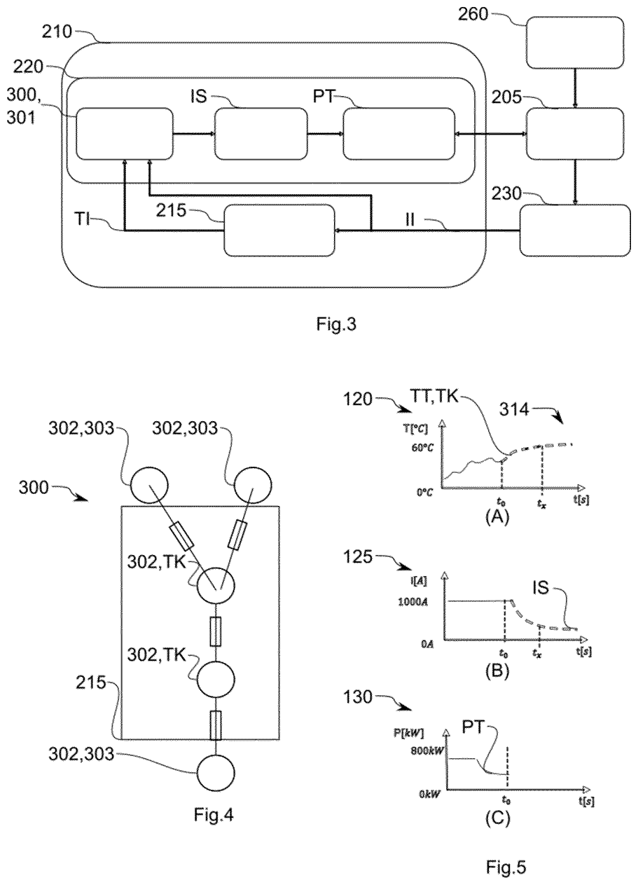

According to FIG. 2, a continuous current IS is calculated 125, taking account of the temperature prediction 315. The continuous current IS is calculated, taking account of a target temperature TT. In this case, the continuous current IS is assumed to be constant, with which a constant cell core temperature TK over time is set, what is known as a stationary state, see also the description for FIGS. 3 and 4.

According to FIG. 2, a degradation of a power limit PT is predicted 130, taking account of the temperature prediction 315 and the continuous current IS. The power limit PT is calculated analytically.

According to FIG. 2, a control command 350 is output 140 for operating the battery cell 315, taking account of the continuous current IS. The power limit PT limits the power that can be withdrawn from the energy storage device 210 and thus the battery cell 215. Thus, the thermal loading of the energy storage device 210 or the battery cell 215 is regulated in a targeted manner.

FIG. 3 schematically shows an information flow for carrying out a method 100 according to an aspect of the disclosure. FIG. 3 is used for further explanation of the method 100 according to FIG. 2 and is described with reference to FIG. 2 and the description thereof.

The capture of the power demand takes place by an actuating device 260 on the vehicle, for example a pedal and/or a button device. The power demand is transmitted to a control unit 205 at the vehicle and analyzed. The control unit 205 requests a setpoint torque from the electric drive 230. The electric drive 230 demands the actual current II from the energy storage device 210. The actual current II is input into the thermal model 300 and brings about a cell core temperature TK of the battery cell 215. According to FIG. 3, the temperature of the battery cell 215 is measured and the corresponding actual temperature TI is input into the thermal model 300. The continuous current IS is predicted 130. In this case, it is assumed that the continuous current IS is a continuous or stationary current. In the stationary state, the change of the temperature TI over time is equal to zero. Therefore, the thermal model 300 is simplified and the continuous current IS can be calculated depending on a chosen target temperature TT. For a known continuous current IS and target temperature TT, the degradation can be represented as a linear equation. The solution of the thermal model 300 can be inserted into the linear equation, which results in a quadratic equation, using which the power limit PT can be determined.

FIG. 4 shows a thermal model 300 for carrying out a method 100 according to an aspect of the disclosure. The thermal model 300 is a model for the battery cell 215. The thermal model 300 has a plurality of nodes 302 that model the battery cell 215. In this case, three of the nodes 302 are formed by temperature sensors 303, of which two of the temperature sensors 303 are used for example for measuring the actual temperature TI and one of the temperature sensors 303 is used for measuring a cooling temperature. Two of the nodes 302 represent the cell core temperature TK. Of these, one of the nodes 302 represents a minimum cell core temperature TK (“cold spot”) and the other of the nodes 302 represents a maximum cell core temperature TK (“hot spot”).

An energy balance can be formulated for each of the nodes 302, in order to calculate the change of the temperature of the node 302 over time. In this case, the energy change due to an input and an output of heat is proportional to the temperature change of the node 302. The energy change in this case results from the power brought about by an electric current I plus the supplied heat minus the dissipated heat. Therefore, a first order linear differential equation and thus a solution of the thermal model 300 consisting of a sum of exponential functions is produced for the development of the temperature 302 of each node 302 over time. The use of the differential equations 301 of the thermal model 300 therefore takes place in order to derive an analytical equation in the case of current boundary conditions, which equation enables a forecast of the temperature development of the cold spot and the hot spot of the battery cell 215. In this case, boundary conditions of the cell core temperature prediction are: coolant temperature is assumed to be constant, ambient temperature is assumed to be constant.

FIG. 5 shows a scenario of carrying out a method 100 according to an aspect of the disclosure. FIG. 5 is described with reference to FIGS. 1 to 4 and the description thereof.

FIG. 5 shows three different curves (FIG. 5 (A), 5 (B), 5 (C)). FIG. 5 (A) in this case shows the carrying out 120 of a temperature prediction 315. FIG. 5 (B) shows, in a manner derived from that, the calculation 125 of the continuous current IS. FIG. 5 (C) shows, based on that, the prediction 130 of a degradation of the power limit PT.

According to FIG. 5 (A), the cell core temperature TK develops up to time to as shown by the curve with the solid line. The temperature prediction 314 takes place from the time t0. The cell core temperature TK develops according to a solution of the thermal model 300, that is to say according to a sum of exponential functions.

The continuous current IS is calculated on the basis of the temperature prediction 314. The continuous current IS results from the stationary state of the respective cell core temperature TK.

The power limit PT is calculated on the basis of the continuous current IS. In this case, a request with respect to maintaining a minimum power can be fulfilled. A minimum continuous current IS can be calculated depending on the current voltage. A maximum temperature can be calculated by the continuous current IS and the thermal model 300. The linear equation for the target temperature TT can be formulated depending on the maximum temperature.

In order to avoid the degradation behavior from being predetermined by the battery cells 215, in an embodiment that is not shown, the method 100 can be applied to a current table that specifies the withdrawable current depending on the temperature. For this, the entire current table is divided into individual straight-line equations. The temperature prediction 314 is solved for each of the straight-line equations. A minimum of the cell core temperature TK is formed from the solutions of the current prediction with the aid of the current table. The calculation is carried out once using the cell core temperature equation for the max. and min. temperature. By forming a minimum of the results of both solution approaches, it is possible to represent both a current prediction over the entire temperature range of the battery cell 215 and a degradation to a continuous current IS which provides sufficient drive power in the hot range.

### LIST OF REFERENCE SIGNS

100 Method
110 Capturing
120 Carrying out
125 Calculating
130 Predicting
140 Outputting
200 Motor vehicle
205 Control unit
210 Energy storage device
215 Battery cell
216 Battery module
220 Battery management unit
225 Electrical energy
230 Electric drive
250 Data processing device
260 Actuating device
300 Thermal model
301 Differential equation
302 Node
303 Temperature sensor
315 Temperature prediction
350 Control command
TI Actual temperature
TK Cell core temperature
TT Target temperature
II Actual current
IS Continuous current
PT Power limit

1-9. (canceled)

10. A method for operating a battery cell for a motor vehicle, the method comprising:
capturing an actual temperature of the battery cell and an actual current relating to a power demand on the battery cell;
determining a temperature prediction for calculating a cell core temperature on a basis of a thermal model of the battery cell, based at least in part on the actual temperature and the actual current;
calculating a continuous current, based at least in part on the temperature prediction;
predicting a degradation of a power limit, based at least in part on the temperature prediction and the continuous current; and
outputting a control command for operating the battery cell, based at least in part on the power limit.

11. The method according to claim 10,
wherein the thermal model comprises an analytically solvable differential equation.

12. The method according to claim 10,
wherein the thermal model comprises a plurality of nodes that model the battery cell and have an energy balance for each of the nodes.

13. The method according to claim 10,
wherein the continuous current is calculated based at least in part on a target temperature.

14. The method according to claim 10,
wherein the power limit is calculated analytically.

15. A computer-readable medium having stored thereon commands that, when executed by a computer, cause the computer to carry out a method comprising:
capturing an actual temperature of a battery cell and an actual current relating to a power demand on the battery cell;
determining a temperature prediction for calculating a cell core temperature on a basis of a thermal model of the battery cell, based at least in part on the actual temperature and the actual current;
calculating a continuous current, based at least in part on the temperature prediction;
predicting a degradation of a power limit, based at least in part on the temperature prediction and the continuous current; and
outputting a control command for operating the battery cell, based at least in part on the power limit.

16. The computer-readable medium according to claim 15,
wherein the thermal model comprises an analytically solvable differential equation.

17. The computer-readable medium according to claim 15,
wherein the thermal model comprises a plurality of nodes that model the battery cell and have an energy balance for each of the nodes.

18. The computer-readable medium according to claim 15,
wherein the continuous current is calculated based at least in part on a target temperature.

19. The computer-readable medium according to claim 15,
wherein the power limit is calculated analytically.

20. A data processing device for a motor vehicle, wherein the data processing device is configured to:
capture an actual temperature of a battery cell and an actual current relating to a power demand on the battery cell;
determine a temperature prediction for calculating a cell core temperature on a basis of a thermal model of the battery cell, based at least in part on the actual temperature and the actual current;
calculate a continuous current, based at least in part on the temperature prediction;
predict a degradation of a power limit, based at least in part on the temperature prediction and the continuous current; and
output a control command for operating the battery cell, based at least in part on the power limit.

21. The data processing device according to claim 20,
wherein the thermal model comprises an analytically solvable differential equation.

22. The data processing device according to claim 20,
wherein the thermal model comprises a plurality of nodes that model the battery cell and have an energy balance for each of the nodes.

23. The data processing device according to claim 20,
wherein the continuous current is calculated based at least in part on a target temperature.

24. The data processing device according to claim 20,
wherein the power limit is calculated analytically.

25. A battery management unit for a motor vehicle comprising:
the data processing device according to claim 20.

26. A motor vehicle comprising:
the battery management unit according to claim 25.
